(19) United States
(12) Patent Application Publication
(10) Pub. No.: US 2024/0107676 A1
(43) Pub. Date: Mar. 28, 2024

(54) CIRCUIT MODULE AND SUBSTRATE MODULE

(71) Applicant: Murata Manufacturing Co., Ltd., Kyoto-fu (JP)

(72) Inventors: Tomohiko SUGIYAMA, Nagaokakyo-shi (JP); Junichi TAKASHIMA, Nagaokakyo-shi (JP); Takuya NAKAGAWA, Nagaokakyo-shi (JP); Mayu SUZUKI, Nagaokakyo-shi (JP); Daisuke NAKASHIMA, Nagaokakyo-shi (JP)

(73) Assignee: Murata Manufacturing Co., Ltd., Kyoto-fu (JP)

(21) Appl. No.: 18/469,479

(22) Filed: Sep. 18, 2023

(30) Foreign Application Priority Data
Sep. 22, 2022 (JP) 2022-151463

(51) Int. Cl. H05K 1/18

(52) U.S. Cl. CPC H05K 1/183; H05K 2201/1003; H05K 2201/10242; H05K 2201/10984

(57) ABSTRACT

A circuit module comprises a substrate module, an electronic component, and a first conductive joining member. The substrate module includes a circuit substrate having an upper main surface and a lower main surface, an insulating member covering the upper main surface of the circuit substrate, an insulating member covering the upper main surface of the circuit substrate, and a first metal pin that passes through the insulating member parallel to a vertical axis and is electrically connected to the circuit substrate. The first metal pin has a first exposed portion. The first exposed portion is exposed from the insulating member to face a right direction. A first outer electrode has a left projecting portion projecting in a left direction from the left surface. A first conductive joining member joins the first exposed portion and the left projecting portion to each other.

### CROSS-REFERENCE TO RELATED APPLICATION

This application claims benefit of priority to Japanese Patent Application No. 2022-151463, filed Sep. 22, 2022, the entire content of which is incorporated herein by reference.

### BACKGROUND

### Technical Field

The present disclosure relates to a circuit module in which an electronic component is mounted on a substrate module.

### Background Art

For example, the three-dimensional package structure described in U.S. Patent Publication No. 2011/0278704 (FIG. 2) is known regarding a circuit module. This three-dimensional package structure includes a semiconductor package and an energy storage element. The energy storage element is mounted on the upper main surface of the semiconductor package with solder.

### SUMMARY

In the three-dimensional package structure described in U.S. Patent Publication No. 2011/0278704 (FIG. 2), there is a demand to check whether a mounting error has occurred in the energy storage element.

Accordingly, the present disclosure provides a circuit module and a substrate module that can easily determine whether a mounting error has occurred in the electronic component.

According to an embodiment of the present disclosure, there is provided a circuit module including a substrate module; an electronic component; and a first conductive joining member, in which the substrate module includes a circuit substrate having an upper main surface and a lower main surface, an insulating member covering the upper main surface of the circuit substrate, an insulating member covering the upper main surface of the circuit substrate, and a first metal pin that passes through the insulating member parallel to a vertical axis and is electrically connected to the circuit substrate. The first metal pin has a first exposed portion. The first exposed portion is exposed from the insulating member to face a right direction. The electronic component includes an electronic component body having a lower surface, a left surface, and a right surface, and a first outer electrode having a left projecting portion projecting in a left direction from the left surface. The first conductive joining member joins the first exposed portion and the left projecting portion to each other.

According to an embodiment of the present disclosure, there is provided a substrate module on which an electronic component is mounted. The substrate module includes a circuit substrate having an upper main surface and a lower main surface; an insulating member covering the upper main surface of the circuit substrate; and a first metal pin and a second metal pin that pass through the insulating member parallel to a vertical axis and are electrically connected to the circuit substrate. The second metal pin is located right of the first metal pin, in which the first metal pin has a first exposed portion. The second metal pin has a second exposed portion. The first exposed portion is exposed from the insulating member to face a right direction, and the second exposed portion is exposed from the insulating member to face a left direction.

According to the present disclosure, it is possible to provide the circuit module and the substrate module that can easily determine whether a mounting error has occurred in the electronic component.

### BRIEF DESCRIPTION OF THE DRAWINGS

FIG. 1 is a sectional view of a circuit module;

FIG. 2 is a top view of the circuit module;

FIG. 3 is a sectional view of a circuit module;

FIG. 4 is a sectional view of a circuit module;

FIG. 5 is a sectional view of a circuit module;

FIG. 6 is a sectional view of a circuit module;

FIG. 7 is a sectional view of a circuit module;

FIG. 8 is a sectional view of a circuit module;

FIG. 9 is a sectional view of a circuit module; and

FIG. 10 is a top view of a circuit module.

### DETAILED DESCRIPTION

### Embodiment

[Structure of Circuit Module]

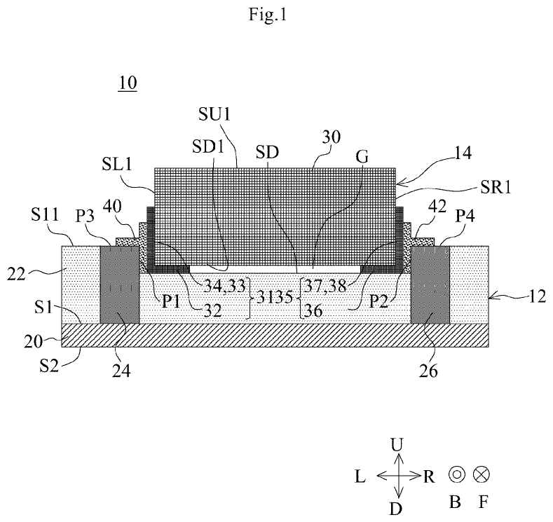

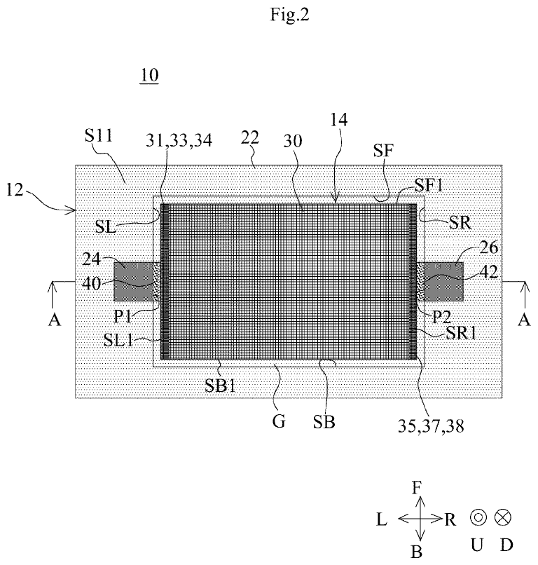

A circuit module 10 according to an embodiment of the present disclosure will be described below with reference to the drawings. FIG. 1 is a sectional view of the circuit module 10. FIG. 2 is a top view of the circuit module 10. FIG. 1 is the sectional view taken along line A-A in FIG. 2.

In this specification, directions are defined as described below. A circuit substrate 20 has an upper main surface S1 and a lower main surface S2. Accordingly, the direction from the upper main surface S1 to the lower main surface S2 is defined as a downward direction. In addition, an electronic component 14 has a rectangular shape as viewed in the downward direction. The long sides of the electronic component 14 extend parallel to a left-right axis as viewed in the downward direction. The short sides of the electronic component 14 extend parallel to a front-rear axis as viewed in the downward direction. It should be noted that the vertical axis, the left-right axis, and the front-rear axis in the present embodiment need not match the vertical axis, the left-right axis, and the front-rear axis when the circuit module 10 is used.

In this specification, unless otherwise specified, individual portions of the first member are defined as described below. A front portion of the first member is the front half of the first member. A rear portion of the first member is the rear half of the first member. A left portion of the first member is the left half of the first member. A right portion of the first member is the right half of the first member. An upper portion of the first member is the upper half of the first member. A lower portion of the first member is the lower half of the first member. A front end of the first member is the end in the front direction of the first member. A rear end of the first member is the end in the rear direction of the first member. A left end of the first member is the end in the left direction of the first member. A right end of the first member is the end in the right direction of the first member. An upper end of the first member is the end in the upward direction of the first member. A lower end of the first member is the end in the downward direction of the first member. A front-end portion of the first member is the front end of the first member and the vicinity thereof. A rear-end portion of the first member is the rear end of the first member and the vicinity thereof. A left-end portion of the first member is the left end of the first member and the vicinity thereof. A right-end portion of the first member is the right end of the first member and the vicinity thereof. An upper-end portion of the first member is the upper end of the first member and the vicinity thereof. A lower-end portion of the first member is the lower end of the first member and the vicinity thereof.

In this specification, an electrical connection between the first member and the second member is electrical conduction between the first member and the second member. Accordingly, the first member and the second member may be in contact with each other, or the first member and the second member need not be in contact with each other. When the first member and the second member are not in contact with each other, an electrically conductive third member is disposed between the first member and the second member.

The circuit module 10 includes a substrate module 12, an electronic component 14, a first conductive joining member 40, and a second conductive joining member 42, as illustrated in FIGS. 1 and 2.

The electronic component 14 is mounted on the substrate module 12. As illustrated in FIG. 1, the substrate module 12 includes the circuit substrate 20, an insulating member 22, a first metal pin 24, and a second metal pin 26. The circuit substrate 20 has a plate shape and is constituted by the upper main surface S1 and the lower main surface S2. The circuit substrate 20 has a rectangular shape as viewed in the downward direction. The two long sides of the circuit substrate 20 extend parallel to the left-right axis. The two short sides of the circuit substrate 20 extend parallel to the front-rear axis. An electric circuit is formed of a conductor layer, which is not illustrated, in the circuit substrate 20. In addition, two electrodes, which are not illustrated, are provided on the upper main surface S1 of the circuit substrate 20.

The insulating member 22 covers the upper main surface S1 of the circuit substrate 20. The insulating member 22 has an upper main surface S11. A recessed portion G is provided in the upper main surface S11 of the insulating member 22. The recessed portion G has a rectangular shape as viewed in the downward direction. The recessed portion G has a left side surface SL facing the right direction, a right side surface SR facing the left direction, a front side surface SF facing the rear direction, a rear side surface SB facing the front direction, and a bottom surface SD facing the upward direction. The left side surface SL and the right side surface SR are orthogonal to the front-rear axis. The front side surface SF and the rear side surface SB are orthogonal to the left-right axis.

The first metal pin 24 and the second metal pin 26 pass through the insulating member 22 parallel to the vertical axis. The first metal pin 24 and the second metal pin 26 are electrically connected to the circuit substrate 20. Specifically, the first metal pin 24 and the second metal pin 26 have bar shapes extending parallel to the vertical axis. In the present embodiment, the first metal pin 24 and the second metal pin 26 have rectangular parallelepiped shapes. The lower end of the first metal pin 24 and the lower end of the second metal pin 26 are in contact with two electrodes, which are not illustrated, provided on the upper main surface S1 of the circuit substrate 20. The second metal pin 26 is located to the right of the first metal pin 24. The materials of the first metal pin 24 and the second metal pin 26 are metals having high conductivity. An example of metals having high conductivity is copper.

The first metal pin 24 has a first exposed portion P1 and a third exposed portion P3. The first exposed portion P1 is exposed from the insulating member 22. More specifically, the first exposed portion P1 is an upper portion of the right surface of the first metal pin 24. The first exposed portion P1 is exposed from the insulating member 22 to face the right direction on the left side surface SL. The first exposed portion P1 is located at a midpoint between the upper end and the lower end of the left side surface SL.

A third exposed portion P3 is exposed from an upper main surface S11 of the insulating member 22. The third exposed portion P3 is an upper surface of the first metal pin 24. Accordingly, the third exposed portion P3 faces the upward direction.

The second metal pin 26 has a second exposed portion P2 and a fourth exposed portion P4. The second exposed portion P2 is exposed from the insulating member 22. More specifically, the second exposed portion P2 is an upper portion of the left surface of the second metal pin 26. The second exposed portion P2 is exposed from the insulating member 22 to face the left direction on the right side surface SR. The second exposed portion P2 is located at a midpoint between the front end and the rear end of the right side surface SR.

The fourth exposed portion P4 is exposed from the upper main surface S11 of the insulating member 22. The fourth exposed portion P4 is an upper surface of the second metal pin 26. Accordingly, the fourth exposed portion P4 faces the upward direction.

The electronic component 14 includes, for example, an inductor. The electronic component 14 includes an electronic component body 30, a first outer electrode 31, and a second outer electrode 35.

The electronic component body 30 has a rectangular parallelepiped shape. The electronic component body 30 has an upper surface SU1, a lower surface SD1, a left surface SL1, a right surface SRL a front surface SF1, and a rear surface SB1. The electronic component body 30 incorporates an inductor formed of a conductor. The electronic component body 30 has a structure including, for example, laminated ceramic layers.

The first outer electrode 31 includes a first bottom surface portion 32 and a first side surface portion 34. The first bottom surface portion 32 is located on the lower surface SD1. The first bottom surface portion 32 has a rectangular shape as viewed in the upward direction. The first bottom surface portion 32 is in contact with the left side of the lower surface SD1. The first side surface portion 34 is located on the left surface SL1. A first side surface portion 34 has a rectangular shape as viewed in the right direction. The first side surface portion 34 is in contact with the lower side of the left surface SL1. Accordingly, the first side surface portion 34 is in contact with the first bottom surface portion 32. The first side portion 34 as described above is a left projecting portion 33 projecting in the left direction from the left surface SL1.

The second outer electrode 35 includes a second bottom surface portion 36 and a second side surface portion 38. The second bottom surface portion 36 is located on the lower surface SD1. The second bottom surface portion 36 has a rectangular shape as viewed in the upward direction. The second bottom surface portion 36 is in contact with the right side of the lower surface SD1. The second side surface portion 38 is located on the right surface SR1. The second side surface portion 38 has a rectangular shape as viewed in the left direction. The second side surface portion 38 is in contact with the lower side of the right surface SR1. Accordingly, the second side surface portion 38 is in contact with the second bottom surface portion 36. The second side surface portion 38 as described above is a right projecting portion 37 projecting in the right direction from the right surface SR1.

The first outer electrode 31 and the second outer electrode 35 as described above are formed by applying a conductive paste to the surface of the electronic component body 30, sintering the conductive paste, and performing Ni plating and Sn plating.

The electronic component 14 as described above is mounted on the substrate module 12. Specifically, the electronic component 14 is located in the recessed portion G as viewed in the downward direction. The electronic component 14 is surrounded by the left side surface SL, the right side surface SR, the front side surface SF, and the rear side surface SB as viewed in the downward direction.

The first conductive joining member 40 joins the first exposed portion P1 and the left projecting portion 33 to each other. Furthermore, the first conductive joining member 40 joins the third exposed portion P3 and the left projecting portion 33 to each other. The left projecting portion 33 is the first side surface portion 34. The first conductive joining member 40 is made of, for example, solder. Accordingly, the first conductive joining member 40 is electrically connected to the first metal pin 24.

The second conductive joining member 42 joins the second exposed portion P2 and the right projecting portion 37 to each other. Furthermore, the second conductive joining member 42 joins the fourth exposed portion P4 and the right projecting portion 37 to each other. The right projecting portion 37 is the second side surface portion 38. The second conductive joining member 42 is made of, for example, solder. Accordingly, the second conductive joining member 42 is electrically connected to the second metal pin 26.

[Effects]

In the circuit module 10, it is possible to easily determine whether a mounting error has occurred in the electronic component 14. More specifically, the first exposed portion P1 is exposed from the insulating member 22 to face the right direction. The left projecting portion 33 projects in the left direction from the left surface SL1. Accordingly, the first exposed portion P1 faces the left projecting portion 33. Therefore, the first conductive joining member 40 joins the first exposed portion P1 and the left projecting portion 33 to each other. Accordingly, a person performing an inspection can visually identify the first conductive joining member 40. As a result, in the circuit module 10, it is possible to easily determine whether a mounting error has occurred in the electronic component 14.

The circuit module 10 suppresses a mounting error from occurring in the electronic component 14. More specifically, the electronic component 14 is located in the recessed portion G as viewed in the downward direction. In particular, in the present embodiment, the electronic component 14 is surrounded by the left side surface SL, the right side surface SR, the front side surface SF, and the rear side surface SB as viewed in the downward direction. This suppresses the circuit module 10 from deviating in the direction orthogonal toward the vertical axis. According to the circuit module 10, a mounting error is suppressed from occurring in the electronic component 14.

In the circuit module 10, a mounting error in the electronic component 14 is also suppressed from occurring due to the following reason. More specifically, the first conductive joining member 40 joins the first exposed portion P1 and the left projecting portion 33 to each other. The second conductive joining member 42 joins the second exposed portion P2 and the right projecting portion 37 to each other. As a result, when the first conductive joining member 40 and the second conductive joining member 42 are melted by heating, surface tension applied to the electronic component 14 by the first conductive joining member 40 is in the left direction, and surface tension applied to the electronic component 14 by the second conductive joining member 42 is in the right direction. Accordingly, in the circuit module 10, surface tension in the upward direction or in the downward direction is less likely to be applied to the electronic component 14. As a result, even when the balance between the surface tension applied to the electronic component 14 by the first conductive joining member 40 and the surface tension applied to the electronic component 14 by the second conductive joining member 42 is lost, the electronic component 14 is less likely to be displaced in the upward direction or in the downward direction. Accordingly, the tombstone phenomenon is less likely to occur in the electronic component 14. Accordingly, in the circuit module 10, a mounting error in the electronic component 14 is also suppressed from occurring due to the following reason.

In the circuit module 10, the electronic component 14 is located in the recessed portion G as viewed in the downward direction. This lowers the position of the circuit module 10. As a result, the height of the circuit module 10 can be reduced.

(First Modification)

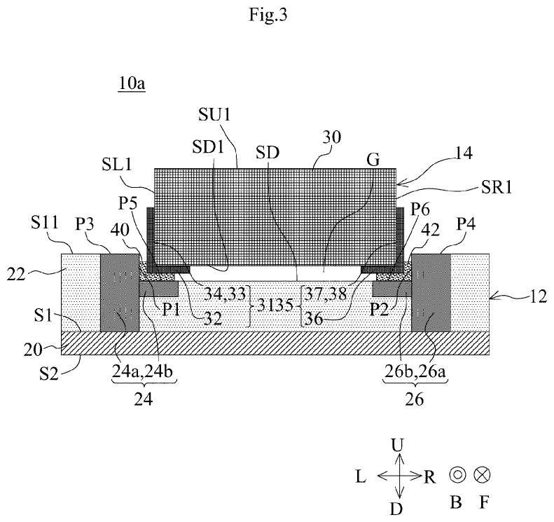

A circuit module 10a according to a first modification will be described below with reference to the drawings. FIG. 3 is a sectional view of the circuit module 10a.

The circuit module 10a differs from the circuit module 10 in the structures of the first metal pin 24 and the second metal pin 26. More specifically, the first metal pin 24 includes a first body 24a extending parallel to the vertical axis and a first projecting portion 24b projecting in the right direction from first body 24a. The first metal pin 24 has a fifth exposed portion P5. The fifth exposed portion P5 is a part of the first projecting portion 24b. The fifth exposed portion P5 is exposed from the insulating member 22 and faces the upward direction. The first conductive joining member 40 joins the fifth exposed portion P5 and the first bottom surface portion 32 of the first outer electrode 31 to each other.

The second metal pin 26 includes a second body 26a extending parallel to the vertical axis and a second projecting portion 26b projecting in the left direction from the second body 26a. The second metal pin 26 has a sixth exposed portion P6. The sixth exposed portion P6 is a part of the second projecting portion 26b. The sixth exposed portion P6 is exposed from the insulating member 22 and faces the upward direction. The second conductive joining member 42 joins the sixth exposed portion P6 and the second bottom surface portion 36 of the second outer electrode 35 to each other. Since the remaining structure of the circuit module 10a is the same as that of the circuit module 10, description thereof is omitted. The circuit module 10a can provide the same effect as the circuit module 10.

(Second Modification)

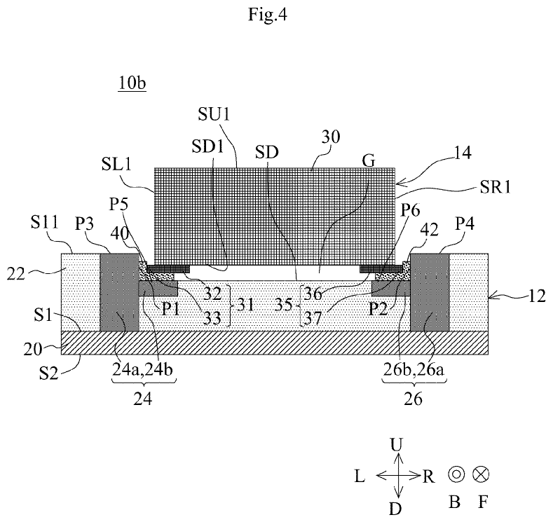

A circuit module 10b according to a second modification will be described below with reference to the drawings. FIG. 4 is a sectional view of the circuit module 10b.

The circuit module 10b differs from the circuit module 10a in the structures of the first outer electrode 31 and the second outer electrode 35. More specifically, the first outer electrode 31 includes the first bottom surface portion 32 located on the lower surface SD1 and the left projecting portion 33 projecting in the left direction from the left end of the first bottom face portion 32. The left projecting portion 33 is not in contact with the left surface SL1 of the electronic component body 30.

The second outer electrode 35 includes the second bottom surface portion 36 located on the lower surface SD1 and the right projecting portion 37 projecting in the right direction from the right end of the second bottom surface portion 36. The right projecting portion 37 is not in contact with the right surface SR1 of the electronic component body 30. Since the other structure of the circuit module 10b is the same as that of the circuit module 10a, description thereof is omitted. The circuit module 10b can provide the same effect as the circuit module 10a.

(Third Modification)

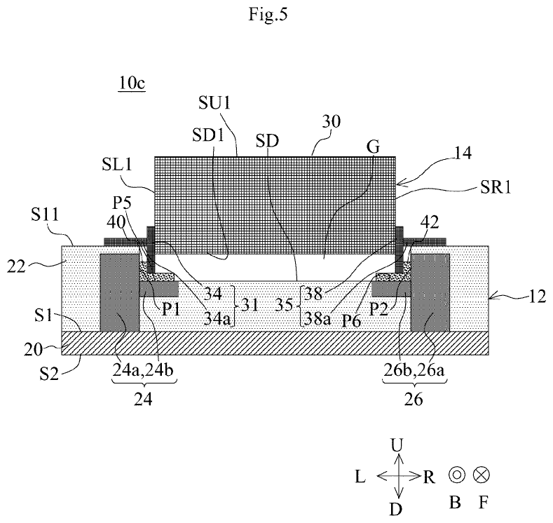

A circuit module 10c according to a third modification will be described below with reference to the drawings. FIG. 5 is a sectional view of the circuit module 10c.

The circuit module 10c differs from the circuit module 10a in that the upper surface of the first metal pin 24 and the upper surface of the second metal pin 26 are not exposed and differs in the structures of the first outer electrode 31 and the second outer electrode 35. More specifically, the first outer electrode 31 includes the first side surface portion 34 and a first support portion 34a. The first side surface portion 34 is located on the left surface SL1. However, the first side surface portion 34 projects in the downward direction from the lower end of the left surface SL1. The first support portion 34a projects in the left direction from the vicinity of the midpoint between the upper end and the lower end of the first side surface portion 34.

The second outer electrode 35 includes the second side surface portion 38 and a second support portion 38a. The second side surface portion 38 is located on the right surface SR1. However, the second side surface portion 38 projects in the downward direction from the lower end of the right surface SR1. The second support portion 38a projects in the right direction from the vicinity of the midpoint between the upper end and the lower end of the second side surface portion 38. Since the other structure of the circuit module 10c is the same as that of the circuit module 10a, description thereof is omitted. The circuit module 10c can provide the same effect as the circuit module 10a.

(Fourth Modification)

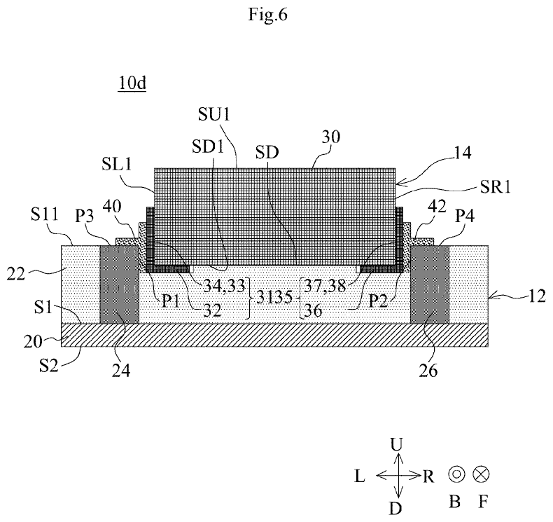

A circuit module 10d according to a fourth modification will be described below with reference to the drawings. FIG. 6 is a sectional view of the circuit module 10d.

The circuit module 10d differs from the circuit module 10 in the shape of the insulating member 22. More specifically, the circuit module 10d has a projection on the bottom surface SD of the insulating member 22. Since the other structure of the circuit module 10d is the same as that of the circuit module 10, description thereof is omitted. The circuit module 10d can provide the same effect as the circuit module 10.

The circuit module 10d has the projection on the bottom surface SD of the insulating member 22. Accordingly, the electronic component 14 is accurately positioned with respect to the substrate module 12.

(Fifth Modification)

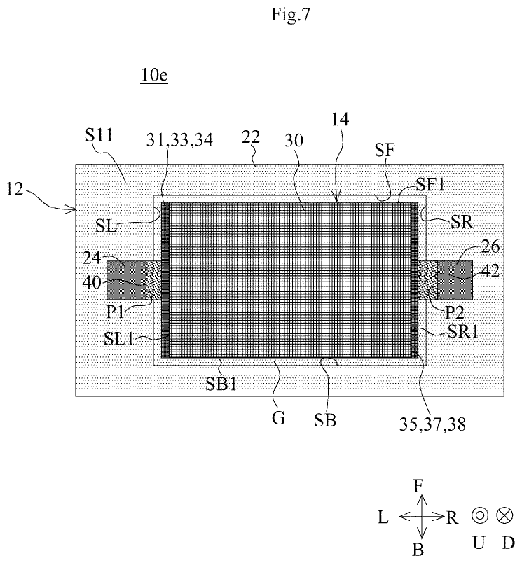

A circuit module 10e according to a fifth modification will be described below with reference to the drawings. FIG. 7 is a sectional view of the circuit module 10e.

The circuit module 10e differs from the circuit module 10 in the positions of the first metal pin 24 and the second metal pin 26. More specifically, the first exposed portion P1 of the first metal pin 24 is located to the left of the left side surface SL. The second exposed portion P2 of the second metal pin 26 is located to the right of the right side surface SR. Since the other structure of the circuit module 10e is the same as that of the circuit module 10, description thereof is omitted. The circuit module 10e can provide the same effect as the circuit module 10.

In the circuit module 10e, the first exposed portion P1 of the first metal pin 24 is located to the left of the left side surface SL. The second exposed portion P2 of the second metal pin 26 is located to the right of the right side surface SR. Accordingly, the electronic component 14 is accurately positioned with respect to the substrate module 12.

In the circuit module 10e, the gap between the first exposed portion P1 and the first outer electrode 31 is large. The gap between the second exposed portion P2 and the second outer electrode 35 is large. Accordingly, a person performing an inspection can visually identify the first conductive joining member 40 and the second conductive joining member 42. As a result, in the circuit module 10e, it is possible to easily determine whether a mounting error has occurred in the electronic component 14.

(Sixth Modification)

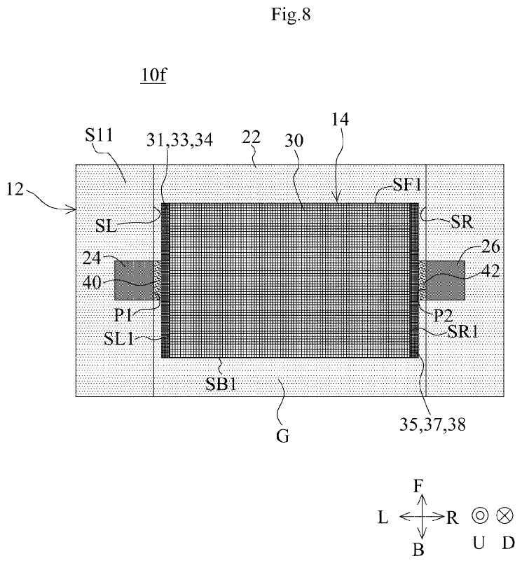

A circuit module 10f according to a sixth modification will be described below with reference to the drawings. FIG. 8 is a sectional view of the circuit module 10f.

The circuit module 10f differs from the circuit module 10 in the shape of the recessed portion G. More specifically, the recessed portion G reaches the front surface and the rear surface of the substrate module 12. Accordingly, the recessed portion G does not have the front side surface SF and the rear side surface SB. Since the other structure of the circuit module 10f is the same as that of the circuit module 10, description thereof is omitted. The circuit module 10f can provide the same effect as the circuit module 10.

(Seventh Modification)

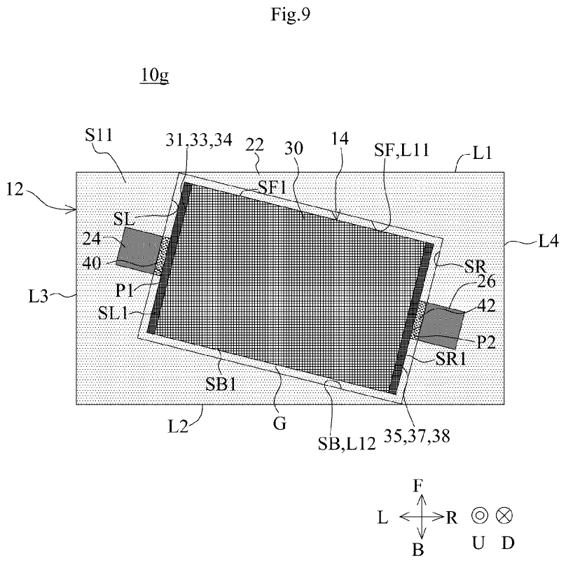

A circuit module 10g according to a seventh modification will be described below with reference to the drawings. FIG. 9 is a sectional view of the circuit module 10g.

The circuit module 10g differs from the circuit module 10 in the disposition of the recessed portion G. More specifically, individual sides of the recessed portion G are not parallel to individual sides of the substrate module 12 as viewed in the downward direction. As viewed in the downward direction, the substrate module 12 has a rectangular shape including a first long side L1, a second long side L2, a first short side L3, and a second short side L4. As viewed in the downward direction, a straight line L11 including the front side surface SF intersects a left portion of first long side L1 at an angle smaller than 90 degrees. As viewed in the downward direction, a straight line L12 including the rear side surface SB intersects a right portion of the second long side L2 at an angle smaller than 90 degrees. Since the other structure of the circuit module 10g is the same as that of the circuit module 10, description thereof is omitted. The circuit module 10g can provide the same effect as the circuit module 10.

In the circuit module 10g, the size of the circuit module 10g in the left-right axis direction can be reduced.

(Eighth Modification)

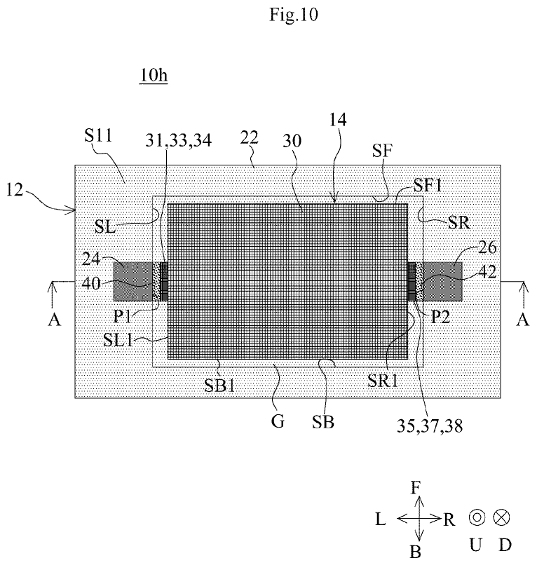

A circuit module 10h according to an eighth modification will be described below with reference to the drawings. FIG. 10 is a top view of the circuit module 10h.

The circuit module 10h differs from the circuit module 10 in the width of the first outer electrode 31 in the front-rear axis direction and the width of the second outer electrode 35 in the front-rear axis direction. More specifically, the width of the first outer electrode 31 in the front-rear direction is substantially the same as the width of the first metal pin 24 in the front-rear direction. The width of the second outer electrode 35 in the front-rear direction is substantially the same as the width of the second metal pin 26 in the front-rear direction. Since the other structure of the circuit module 10h is the same as that of the circuit module 10, description thereof is omitted. The circuit module 10h can provide the same effect as the circuit module 10.

### Other Embodiments

The circuit module according to the present disclosure is not limited to the circuit modules 10 and 10a to 10h, and changes can be made within the scope of the concept of the present disclosure. In addition, any combination of the structures of the circuit modules 10 and 10a to 10h is possible.

It should be noted that the recessed portion G is not a constituent feature. Accordingly, the upper main surface S11 may be flat. In this case, the first metal pin 24 and the second metal pin 26 project in the upward direction from the upper main surface S11.

It should be noted that an electronic component such as an integrated circuit (IC) may be provided in the insulating member 22 of the substrate module 12.

The first conductive joining member 40 and the second conductive joining member 42 may be made of materials other than solder. The first conductive joining member 40 and the second conductive joining member 42 may each be, for example, a conductive adhesive.

It should be noted that the shapes of the first metal pin 24 and the second metal pin 26 are not limited to rectangular parallelepipeds. An example of the shapes of the first metal pin 24 and the second metal pin 26 is a cylinder.

It should be noted that the electronic component 14 may incorporate circuit elements other than the inductor. The circuit elements other than the inductor are, for example, an IC, a resistor, and the like.

It should be noted that the electronic component 14 may be a transformer containing two inductors. In this case, the electronic component 14 may include two first outer electrodes 31 and two second outer electrodes 35.

The present disclosure has the following structures.

(1) A circuit module comprising a substrate module; an electronic component; and a first conductive joining member. The substrate module includes a circuit substrate having an upper main surface and a lower main surface, an insulating member covering the upper main surface of the circuit substrate, an insulating member covering the upper main surface of the circuit substrate, and a first metal pin that passes through the insulating member parallel to a vertical axis and is electrically connected to the circuit substrate. The first metal pin has a first exposed portion. The first exposed portion is exposed from the insulating member to face a right direction. The electronic component includes an electronic component body having a lower surface, a left surface, and a right surface, and a first outer electrode having a left projecting portion projecting in a left direction from the left surface. The first conductive joining member joins the first exposed portion and the left projecting portion to each other.

(2) The circuit module according to (1), further comprising a second conductive joining member. The substrate module further includes a second metal pin that passes through the insulating member parallel to the vertical axis and is electrically connected to the circuit substrate, the second metal pin being located right of the first metal pin. The second metal pin has a second exposed portion, the second exposed portion being exposed from the insulating member to face the left direction. The electronic component further includes a second outer electrode having a right projecting portion projecting in the right direction from the right surface. The second conductive joining member joins the second exposed portion and the right projecting portion to each other.

(3) The circuit module according to (2), wherein the insulating member has an upper main surface, and the upper main surface of the insulating member is provided with a recessed portion having a left side surface facing the right direction, a right side surface facing the left direction, and a bottom surface. Also, the first exposed portion is exposed from the insulating member on the left side surface, the second exposed portion is exposed from the insulating member on the right side surface, and the electronic component is located in the recessed portion as viewed in a downward direction.

(4) The circuit module according to claim 3, wherein the recessed portion further has a front side surface facing a rear direction and a rear side surface facing a front direction, and the electronic component is surrounded by the left side surface, the right side surface, the front side surface, and the rear side surface as viewed in the downward direction.

(5) The circuit module according to claim 4, wherein the substrate module has a rectangular shape including a first long side, a second long side, a first short side, and a second short side as viewed in the downward direction. Also, a straight line including the front side surface intersects a left portion of the first long side at an angle smaller than 90 degrees as viewed in the downward direction, and a straight line including the rear side surface intersects a right portion of the second long side at an angle smaller than 90 degrees as viewed in the downward direction.

(6) The circuit module according to any one of (3) to (5), wherein the first metal pin further has a third exposed portion, and the second metal pin further has a fourth exposed portion. The third exposed portion is exposed from the upper main surface of the insulating member. The fourth exposed portion is exposed from the upper main surface of the insulating member. The first conductive joining member joins the third exposed portion and the left projecting portion to each other, and the second conductive joining member joins the fourth exposed portion and the right projecting portion to each other.

(7) The circuit module according to (2), wherein the insulating member has an upper main surface. The upper main surface of the insulating member is provided with a recessed portion having a left side surface facing the right direction, a right side surface facing the left direction, and a bottom surface. The first exposed portion is located left of the left side surface. The second exposed portion is located right of the right side surface, and the electronic component is located in the recessed portion as viewed in a downward direction.

(8) The circuit module according to any one of (1) to (7), wherein the first outer electrode includes a first bottom surface portion located on the lower surface and a first side surface portion located on the left surface, and the first side surface portion is the left projecting portion.

(9) The circuit module according to any one of (1) to (7), wherein the first outer electrode includes a first bottom surface portion located on the lower surface and the left projecting portion projecting in the left direction from a left end of the first bottom surface portion.

(10) The circuit module according any one of (1) to (9), wherein the first metal pin includes a first body extending parallel to the vertical axis and a first projecting portion projecting in the right direction from the first body. Also, the first metal pin has a fifth exposed portion. The fifth exposed portion is a part of the first projecting portion, and the fifth exposed portion is exposed from the insulating member and faces an upward direction. The first conductive joining member joins the fifth exposed portion and the first outer electrode to each other.

(11) A substrate module on which an electronic component is mounted. The substrate module comprises a circuit substrate having an upper main surface and a lower main surface; an insulating member covering the upper main surface of the circuit substrate; and a first metal pin and a second metal pin that pass through the insulating member parallel to a vertical axis and are electrically connected to the circuit substrate, the second metal pin being located right of the first metal pin. The first metal pin has a first exposed portion, and the second metal pin has a second exposed portion. The first exposed portion is exposed from the insulating member to face a right direction, and the second exposed portion is exposed from the insulating member to face a left direction.

What is claimed is:

1. A circuit module comprising:
a substrate module;
an electronic component; and
a first conductive joining member,
wherein the substrate module includes a circuit substrate having an upper main surface and a lower main surface, an insulating member covering the upper main surface of the circuit substrate, an insulating member covering the upper main surface of the circuit substrate, and a first metal pin that passes through the insulating member parallel to a vertical axis and is electrically connected to the circuit substrate,
the first metal pin has a first exposed portion,
the first exposed portion is exposed from the insulating member to face a right direction,
the electronic component includes an electronic component body having a lower surface, a left surface, and a right surface, and a first outer electrode having a left projecting portion projecting in a left direction from the left surface, and
the first conductive joining member joins the first exposed portion and the left projecting portion to each other.

2. The circuit module according to claim 1, further comprising:
a second conductive joining member,
wherein the substrate module further includes a second metal pin that passes through the insulating member parallel to the vertical axis and is electrically connected to the circuit substrate, the second metal pin being located right of the first metal pin,
the second metal pin has a second exposed portion, the second exposed portion being exposed from the insulating member to face the left direction,
the electronic component further includes a second outer electrode having a right projecting portion projecting in the right direction from the right surface, and
the second conductive joining member joins the second exposed portion and the right projecting portion to each other.

3. The circuit module according to claim 2, wherein
the insulating member has an upper main surface,
the upper main surface of the insulating member includes a recessed portion having a left side surface facing the right direction, a right side surface facing the left direction, and a bottom surface,
the first exposed portion is exposed from the insulating member on the left side surface,
the second exposed portion is exposed from the insulating member on the right side surface, and
the electronic component is in the recessed portion as viewed in a downward direction.

4. The circuit module according to claim 3, wherein
the recessed portion further has a front side surface facing a rear direction and a rear side surface facing a front direction, and
the electronic component is surrounded by the left side surface, the right side surface, the front side surface, and the rear side surface as viewed in the downward direction.

5. The circuit module according to claim 4, wherein
the substrate module has a rectangular shape including a first long side, a second long side, a first short side, and a second short side as viewed in the downward direction,
a straight line including the front side surface intersects a left portion of the first long side at an angle smaller than 90 degrees as viewed in the downward direction and
a straight line including the rear side surface intersects a right portion of the second long side at an angle smaller than 90 degrees as viewed in the downward direction.

6. The circuit module according to claim 3, wherein
the first metal pin further has a third exposed portion,
the second metal pin further has a fourth exposed portion,
the third exposed portion is exposed from the upper main surface of the insulating member,
the fourth exposed portion is exposed from the upper main surface of the insulating member,
the first conductive joining member joins the third exposed portion and the left projecting portion to each other, and
the second conductive joining member joins the fourth exposed portion and the right projecting portion to each other.

7. The circuit module according to claim 2, wherein
the insulating member has an upper main surface,
the upper main surface of the insulating member includes a recessed portion having a left side surface facing the right direction, a right side surface facing the left direction, and a bottom surface,
the first exposed portion is located left of the left side surface,
the second exposed portion is located right of the right side surface, and
the electronic component is located in the recessed portion as viewed in a downward direction.

8. The circuit module according to claim 1, wherein
the first outer electrode includes a first bottom surface portion located on the lower surface and a first side surface portion located on the left surface, and
the first side surface portion is the left projecting portion.

9. The circuit module according to claim 1, wherein
the first outer electrode includes a first bottom surface portion located on the lower surface and the left projecting portion projecting in the left direction from a left end of the first bottom surface portion.

10. The circuit module according to claim 1, wherein
the first metal pin includes a first body extending parallel to the vertical axis and a first projecting portion projecting in the right direction from the first body,
the first metal pin has a fifth exposed portion,
the fifth exposed portion is a part of the first projecting portion,
the fifth exposed portion is exposed from the insulating member and faces an upward direction, and
the first conductive joining member joins the fifth exposed portion and the first outer electrode to each other.

11. The circuit module according to claim 4, wherein
the first metal pin further has a third exposed portion,
the second metal pin further has a fourth exposed portion,
the third exposed portion is exposed from the upper main surface of the insulating member,
the fourth exposed portion is exposed from the upper main surface of the insulating member,
the first conductive joining member joins the third exposed portion and the left projecting portion to each other, and
the second conductive joining member joins the fourth exposed portion and the right projecting portion to each other.

12. The circuit module according to claim 5, wherein
the first metal pin further has a third exposed portion,
the second metal pin further has a fourth exposed portion,
the third exposed portion is exposed from the upper main surface of the insulating member,
the fourth exposed portion is exposed from the upper main surface of the insulating member,
the first conductive joining member joins the third exposed portion and the left projecting portion to each other, and
the second conductive joining member joins the fourth exposed portion and the right projecting portion to each other.

13. The circuit module according to claim 2, wherein
the first outer electrode includes a first bottom surface portion located on the lower surface and a first side surface portion located on the left surface, and
the first side surface portion is the left projecting portion.

14. The circuit module according to claim 3, wherein
the first outer electrode includes a first bottom surface portion located on the lower surface and a first side surface portion located on the left surface, and
the first side surface portion is the left projecting portion.

15. The circuit module according to claim 4, wherein
the first outer electrode includes a first bottom surface portion located on the lower surface and a first side surface portion located on the left surface, and
the first side surface portion is the left projecting portion.

16. The circuit module according to claim 2, wherein
the first outer electrode includes a first bottom surface portion located on the lower surface and the left projecting portion projecting in the left direction from a left end of the first bottom surface portion.

17. The circuit module according to claim 3, wherein
the first outer electrode includes a first bottom surface portion located on the lower surface and the left projecting portion projecting in the left direction from a left end of the first bottom surface portion.

18. The circuit module according to claim 2, wherein
the first metal pin includes a first body extending parallel to the vertical axis and a first projecting portion projecting in the right direction from the first body,
the first metal pin has a fifth exposed portion,
the fifth exposed portion is a part of the first projecting portion,
the fifth exposed portion is exposed from the insulating member and faces an upward direction, and
the first conductive joining member joins the fifth exposed portion and the first outer electrode to each other.

19. The circuit module according to claim 3, wherein
the first metal pin includes a first body extending parallel to the vertical axis and a first projecting portion projecting in the right direction from the first body,
the first metal pin has a fifth exposed portion,
the fifth exposed portion is a part of the first projecting portion,
the fifth exposed portion is exposed from the insulating member and faces an upward direction, and
the first conductive joining member joins the fifth exposed portion and the first outer electrode to each other.

20. A substrate module on which an electronic component is mounted, the substrate module comprising:
a circuit substrate having an upper main surface and a lower main surface;
an insulating member covering the upper main surface of the circuit substrate; and
a first metal pin and a second metal pin that pass through the insulating member parallel to a vertical axis and are electrically connected to the circuit substrate, the second metal pin being located right of the first metal pin,
wherein the first metal pin has a first exposed portion,
the second metal pin has a second exposed portion,
the first exposed portion is exposed from the insulating member to face a right direction, and
the second exposed portion is exposed from the insulating member to face a left direction.
